(19) United States
(12) Patent Application Publication
(10) Pub. No.: US 2009/0001582 A1
(43) Pub. Date: Jan. 1, 2009

(54) SEMICONDUCTOR DEVICE WITH METAL GATE AND METHOD FOR FABRICATING THE SAME

(75) Inventors: Ky-Hyun HAN, Ichon-shi (KR); Ki-Won Nam, Ichon-shi (KR)

Correspondence Address: TOWNSEND AND TOWNSEND AND CREW, LLP, TWO EMBARCADERO CENTER, EIGHTH FLOOR, SAN FRANCISCO, CA, 94111-3834, US

(73) Assignee: Hyunix Semiconductor Inc., Ichon-shi (KR)

(21) Appl. No.: 11/955,327

(22) Filed: Dec. 12, 2007

(30) Foreign Application Priority Data
Jun. 27, 2007 (KR) 10-2007-0063618

(51) Int. Cl. H01L 23/48; H01L 21/4763

(52) U.S. Cl. 257/751; 438/627; 257/E21.495; 257/E23.01

(57) ABSTRACT

A semiconductor device includes a substrate, a gate dielectric layer over the substrate, a silicon electrode over the gate dielectric layer, wherein the silicon electrode comprises a damascene pattern, a diffusion barrier layer on a bottom and a sidewall of the damascene pattern, and a metal electrode over the diffusion barrier layer, wherein the metal electrode fills the damascene pattern.

### CROSS-REFERENCE TO RELATED APPLICATIONS

The present invention claims priority of Korean patent application number 2007-0063618, filed on Jun. 27, 2007, which is incorporated by reference in its entirety.

### BACKGROUND OF THE INVENTION

The present invention relates to a method for fabricating a semiconductor device, and more particularly, to a semiconductor device with a metal gate and a method for fabricating the same.

To reduce gate resistance in the fabrication of a semiconductor device, a metal gate process including a metal electrode such as a tungsten layer is commonly employed. Typically, a gate dielectric layer serving as an electron pathway must maintain a high quality. If, however, a metal electrode is directly formed over the gate dielectric layer, the gate dielectric layer may be undesirably etched due to its low etch selectivity ratio during an etch process of the metal layer.

Therefore, a metal gate is typically formed by depositing a metal electrode after depositing a silicon electrode to a predetermined thickness, because the silicon electrode exhibits a high etch selectivity ratio with respect to the gate dielectric layer in spite of its poor resistance characteristic.

FIG. 1 is a cross-sectional view of a typical metal gate.

Referring to FIG. 1, a gate dielectric layer 12 is formed over a substrate 11. A silicon electrode 13, a diffusion barrier layer 14, a metal electrode 15 and a gate hard mask layer 16 are stacked over the gate dielectric layer 12. The silicon electrode 13 includes a polysilicon layer, and the metal electrode 15 includes a tungsten layer.

According to the typical metal gate, however, it is difficult to realize high-speed performance because a large thickness (see ‘D’ of FIG. 1) of the silicon electrode 13 results in a disadvantage in resistance.

### SUMMARY OF THE INVENTION

Embodiments of the present invention provide a semiconductor device with a metal gate capable of reducing resistance as well as preventing etch loss of a gate dielectric layer, and a method for fabricating the semiconductor device.

In accordance with a first aspect of the present invention, there is provided a semiconductor device including a substrate, a gate dielectric layer over the substrate, a silicon electrode over the gate dielectric layer, wherein the silicon electrode comprises a damascene pattern, a diffusion barrier layer on a bottom and a sidewall of the damascene pattern, and a metal electrode over the diffusion barrier layer, wherein the metal electrode fills the damascene pattern.

In accordance with a second aspect of the present invention, there is provided a semiconductor device including a substrate, a gate dielectric layer over the substrate, a metal electrode over the gate dielectric layer, and a diffusion barrier layer between the metal electrode and the gate dielectric layer, wherein the diffusion barrier layer covers a sidewall of the metal electrode.

In accordance with a third aspect of the present invention, there is provided a method for fabricating a semiconductor device. The method includes providing a substrate, forming a gate dielectric layer over the substrate, forming a silicon-containing layer over the gate dielectric layer, forming a damascene pattern in the silicon-containing layer, forming a diffusion barrier layer on a bottom and a sidewall of the damascene pattern, forming a metal electrode over the diffusion barrier layer, wherein the metal electrode fills the damascene pattern, forming a gate hard mask layer over the metal electrode, wherein the gate hard mask layer has a greater linewidth than the damascene pattern, and sequentially etching the silicon-containing layer and the gate dielectric layer using the gate hard mask layer as an etch barrier.

In accordance with a fourth aspect of the present invention, there is provided a method for fabricating a semiconductor device. The method includes providing a substrate, forming a gate dielectric layer over the substrate, forming a silicon-containing layer over the gate dielectric layer, wherein the silicon-containing layer comprises a damascene pattern, forming a diffusion barrier layer over the silicon-containing layer, forming a metal electrode over the diffusion barrier layer, wherein a portion of the metal electrode fills the damascene pattern, forming a gate hard mask layer over the metal electrode, wherein the gate hard mask layer has a greater linewidth than the damascene pattern, etching the metal electrode and the diffusion barrier layer using the gate hard mask layer as an etch barrier, forming a passivation layer on an exposed sidewall of the metal electrode, and sequentially etching the silicon-containing layer and the gate dielectric layer using the gate hard mask layer and the passivation layer as an etch barrier.

### BRIEF DESCRIPTION OF THE DRAWINGS

FIG. 1 is a cross-sectional view of a typical metal gate.

FIGS. 2A to 2E are cross-sectional views of a method for fabricating a metal gate of a semiconductor device in accordance with a first embodiment of the present invention.

FIGS. 3A to 3F are cross-sectional views of a method for fabricating a metal gate of a semiconductor device in accordance with a second embodiment of the present invention.

FIGS. 4A to 4E are cross-sectional views of a method for fabricating a metal gate of a semiconductor device in accordance with a third embodiment of the present invention.

FIGS. 5A to 5F are cross-sectional views of a method for fabricating a metal gate of a semiconductor device in accordance with a fourth embodiment of the present invention.

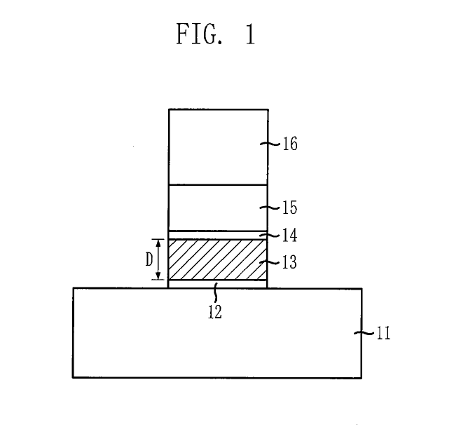

### DESCRIPTION OF SPECIFIC EMBODIMENTS

Embodiments of the present invention relate to a semiconductor device with a metal gate and a method for fabricating the same.

In embodiments of the invention, a thickness of a silicon electrode is reduced because it exhibits a poor resistance characteristic in a metal gate. Therefore, a space between a gate dielectric layer and a metal electrode decreases, thus reducing gate resistance.

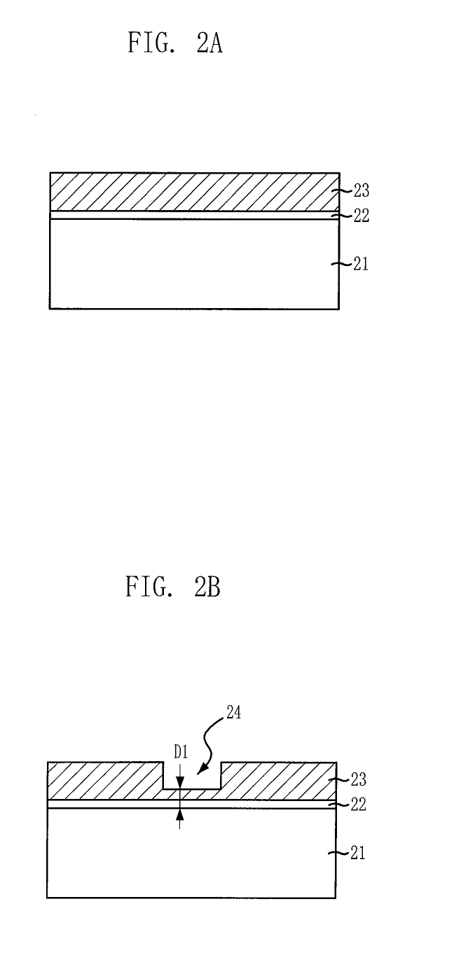

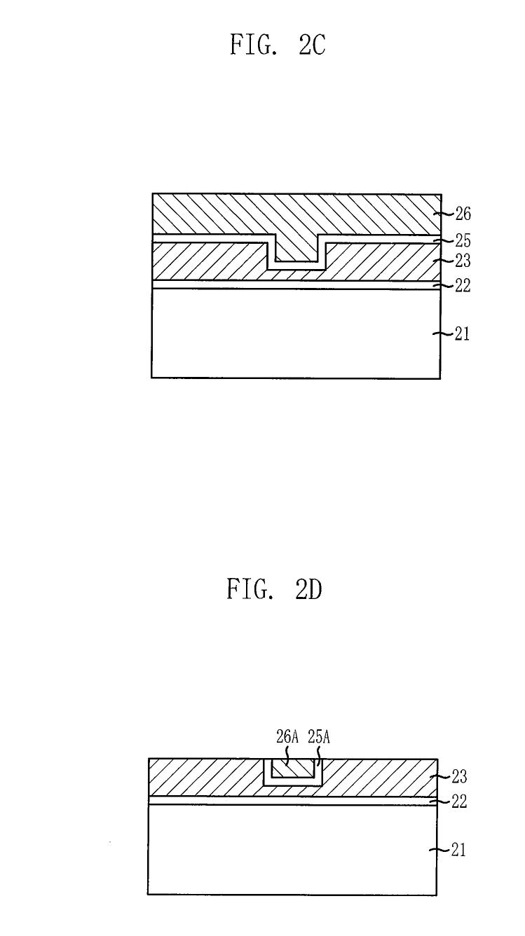

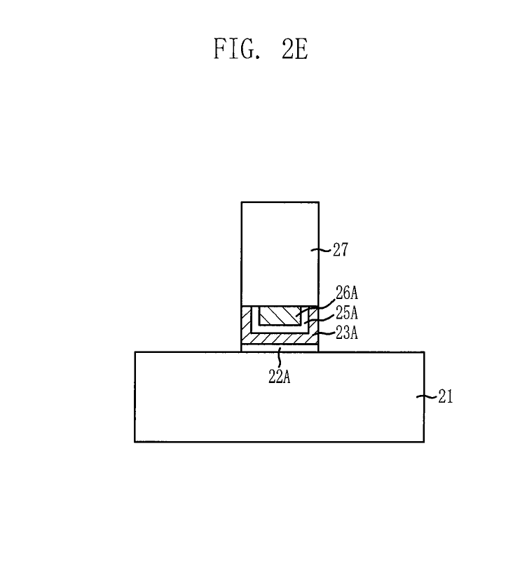

FIGS. 2A to 2E are cross-sectional views of a method for fabricating a metal gate of a semiconductor device in accordance with a first embodiment of the present invention.

Referring to FIG. 2A, a gate dielectric layer 22 is formed over a substrate 21. The substrate 21 may include a silicon substrate, in which a recess pattern or a bulb recess pattern may be formed in advance for increasing a channel length. The gate dielectric layer 22 may include a silicon oxide layer.

A silicon-containing layer 23 having a predetermined thickness is deposited over the gate dielectric layer 22. The silicon-containing layer 23 may include a polysilicon layer.

Referring to FIG. 2B, the silicon-containing layer 23 may be etched to a predetermined depth to form a damascene pattern 24. The damascene pattern 24 is a line pattern formed in a region where a gate will be formed. The damascene pattern 24 is formed such that the gate dielectric layer 22 is not exposed. That is, the silicon-containing layer 23 having a predetermined thickness D1 remains under the damascene pattern 24.

Referring to FIG. 2C, a first metal layer 25 is deposited over the silicon-containing layer 23 with the damascene pattern 24. The first metal layer 25 may include a titanium (Ti) layer. For example, the first metal layer 25 may include a bilayered structure of a titanium (Ti) layer and a tungsten nitride (WN) layer. Alternatively, the first metal layer 25 may include a multi-stacked structure of a Ti layer, a titanium nitride (TiN) layer and a WN layer.

Thereafter, a second metal layer 26 is deposited over the first metal layer 25 to fill the damascene pattern 24. The second metal layer 26 includes a tungsten (W) layer, and may be deposited using a chemical vapor deposition (CVD) process.

Referring to FIG. 2D, a polish process is performed to leave a diffusion barrier layer 25A resulting from the first metal layer 25 and a metal electrode 26A resulting from the second metal layer 26, inside the damascene pattern 24. The diffusion barrier layer 25A is formed on a bottom and a sidewall of the damascene pattern 24, and the metal electrode 26A is surrounded by the diffusion barrier layer 25A and fills the damascene pattern 24.

The polish process may be performed using a chemical mechanical polishing (CMP) process. The diffusion barrier layer 25A prevents interdiffusion between the metal electrode 26A and a silicon electrode to be formed from the silicon-containing layer 23.

Referring to FIG. 2E, a gate hard mask layer (not shown) is deposited over the silicon-containing layer 23 with the metal electrode 26A filling the damascene pattern 24. Thereafter the gate hard mask layer is patterned to form a gate hard mask pattern 27. A patterning linewidth of the gate hard mask layer is greater than a linewidth of the damascene pattern 24. The gate hard mask layer includes a nitride layer, particularly a silicon nitride layer.

The silicon-containing layer 23 is etched using the gate hard mask pattern 27 as an etch barrier to form a silicon electrode 23A. As a result, the gate dielectric layer 22 is exposed. Since the silicon-containing layer 23 is a polysilicon layer, the gate dielectric layer made of oxide material has a high etch selectivity ratio to the polysilicon layer so that the gate dielectric layer 22 is not etched.

A linewidth of the silicon electrode 23A is equal to a linewidth of the gate hard mask pattern 27. Hence, sidewalls of the metal electrode 26A and the diffusion barrier layer 25A are surrounded by the silicon electrode 23A. Because the diffusion barrier layer 25A is formed on the bottom and the sidewall of the damascene pattern 24, the diffusion barrier layer 25A can sufficiently prevent the interdiffusion between the metal electrode 26A and the silicon electrode 23A.

The gate dielectric layer 22 is etched to complete a gate patterning process, resulting in a gate dielectric pattern 22A under the silicon electrode 23A.

By the above-described processes, the gate resistance can be reduced as the thickness of the silicon electrode 23A disposed over the gate dielectric layer 22 is reduced while employing the metal electrode 26A.

Further, since the gate dielectric layer 22 is exposed during the etch process of the silicon-containing layer 23, the gate dielectric layer 22 is not etched during the etch process of the silicon-containing layer 23.

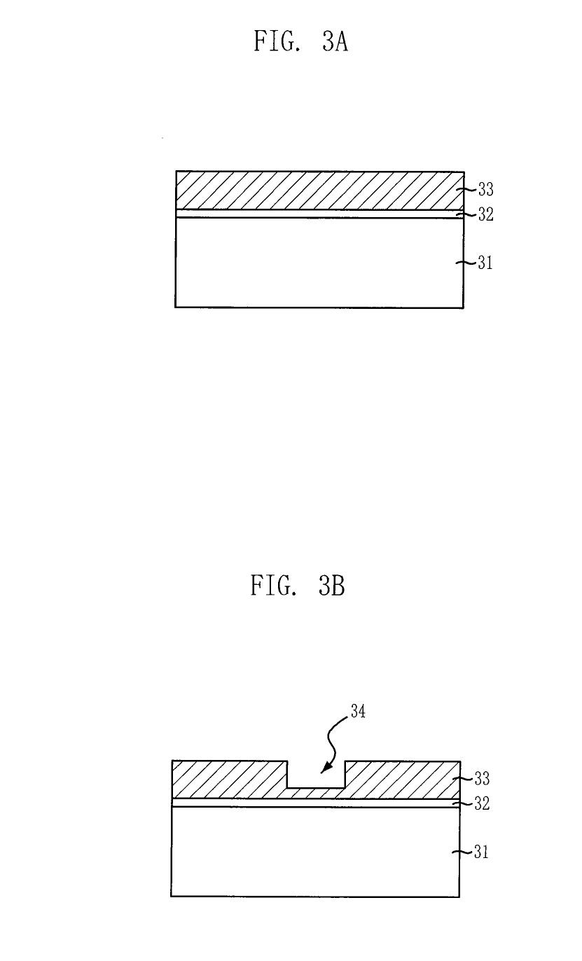

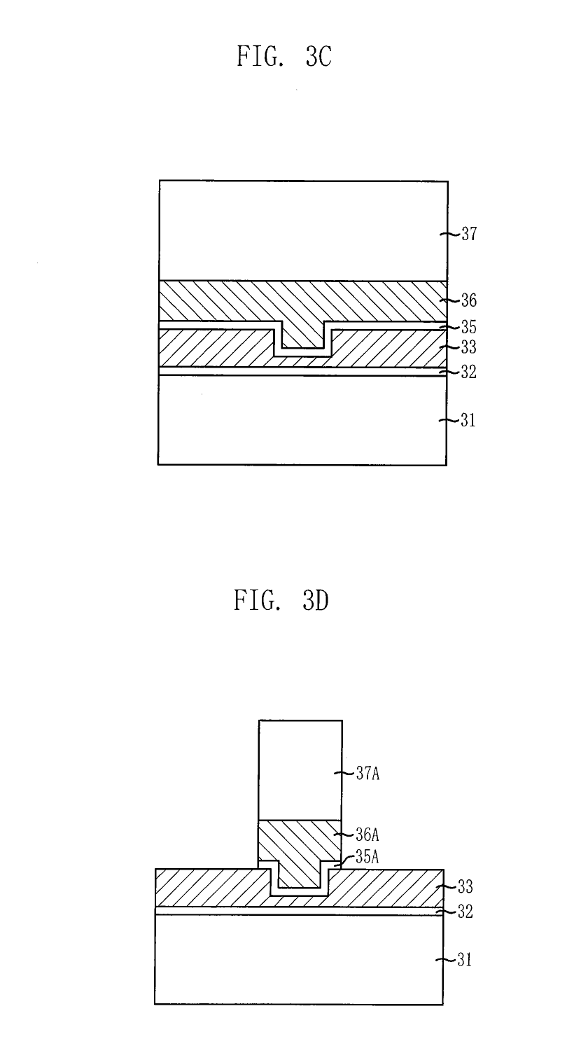

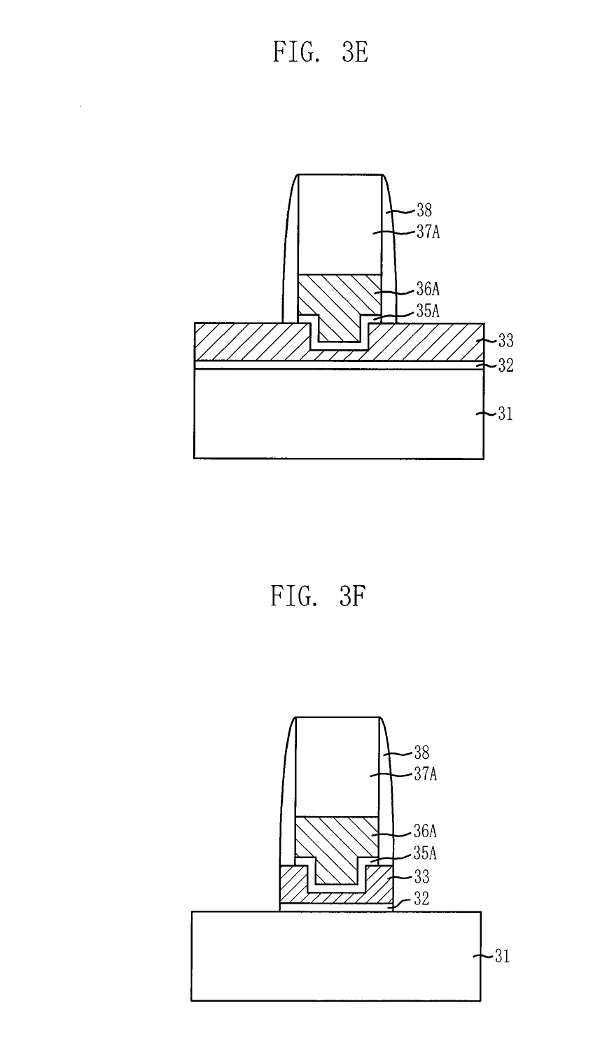

FIGS. 3A to 3F are cross-sectional views of a method for fabricating a metal gate of a semiconductor device in accordance with a second embodiment of the present invention.

Referring to FIG. 3A, a gate dielectric layer 32 is formed over a substrate 31. The substrate 31 may include a silicon substrate, in which a recess pattern or a bulb recess pattern may be formed in advance for increasing a channel length. The gate dielectric layer 32 may include a silicon oxide layer.

A silicon-containing layer 33 having a predetermined depth is deposited over the gate dielectric layer 32. The silicon-containing layer 33 may include a polysilicon layer.

Referring to FIG. 3B, the silicon-containing layer 33 may be etched to a predetermined depth to form a damascene pattern 34. The damascene pattern 34 is a line pattern formed in a region where a gate will be formed. The damascene pattern 34 is formed such that the gate dielectric layer 32 is not exposed. That is, the silicon-containing layer 33 having a predetermined thickness remains under the damascene pattern 34.

Referring to FIG. 3C, a first metal layer 35 is deposited over the silicon-containing layer 33 with the damascene pattern 34. The first metal layer 35 may include a Ti layer. For example, the first metal layer 35 may include a bilayered structure of a Ti layer and a WN layer. Alternatively, the first metal layer 35 may include a multi-stacked structure of a Ti layer, a TiN layer and a WN layer.

A second metal layer 36 is deposited over the first metal layer 35 to fill the damascene pattern 34. The second metal layer 36 includes a tungsten layer, and may be deposited using a chemical vapor deposition (CVD) process.

A gate hard mask layer 37 is formed over the second metal layer 36. The gate hard mask layer 37 includes a nitride layer, particularly a silicon nitride layer.

Referring to FIG. 3D, the gate hard mask layer 37 is patterned to form a gate hard mask pattern 37A. Specifically, the patterning process of the gate hard mask layer 37 is performed using a photoresist layer (not shown) as an etch barrier. A patterning linewidth of the gate hard mask pattern 37A is greater than a linewidth of the damascene pattern 34.

The second metal layer 36 and the first metal layer 35 are etched using the gate hard mask pattern 37A as an etch barrier, thus forming a diffusion barrier layer 35A resulting from the first metal layer 35 and a metal electrode 36A resulting from the second metal layer 36.

The diffusion barrier layer 35A is formed on a bottom and a sidewall of the damascene pattern 34. Both ends of the diffusion barrier layer 35A extend to top corners of the damascene pattern 34. The metal electrode 36A is formed to a predetermined thickness over the damascene pattern 34 while filling the damascene pattern 34.

The diffusion barrier layer 35A prevents inter-diffusion between the metal electrode 36A and a silicon electrode to be formed from the silicon-containing layer 33.

Referring to FIG. 3E, a passivation layer 38 is formed on the sidewalls of the gate hard mask pattern 37A and the metal electrode 36A. The passivation layer 38 also covers the exposed sidewalls of the diffusion barrier layer 35A.

The passivation layer 38 is formed as a spacer through a blanket-etch process after depositing a nitride layer. The passivation layer 38 prevents the metal electrode 36A from being oxidized during a subsequent thermal process, e.g., a gate re-oxidation process.

Referring to FIG. 3F, the silicon-containing layer 33 is etched using the gate hard mask pattern 37A and the passivation layer 38 as an etch barrier to form a silicon electrode 33A. As a result, the gate dielectric layer 32 is exposed. Since the silicon-containing layer 33 is a polysilicon layer, the gate dielectric layer made of oxide material has a high etch selectivity ratio to the polysilicon layer so that the gate dielectric layer 32 is not etched.

A linewidth of the silicon electrode 33A is greater than a linewidth of the gate hard mask pattern 37A due to the passivation layer 38. Hence, sidewalls of the metal electrode 36A and the diffusion barrier layer 35A are surrounded by the silicon electrode 33A. Because the diffusion barrier layer 35A is formed on the bottom and sidewalls of the damascene pattern 34, the diffusion barrier layer 35A can sufficiently prevent the inter-diffusion between the metal electrode 36A and the silicon electrode 33A.

The gate dielectric layer 32 is etched to complete a gate patterning process, resulting in a gate dielectric pattern 32A under the silicon electrode 33A.

By the above-described processes, the gate resistance can be reduced as the thickness of the silicon electrode 33A disposed over the gate dielectric layer 32 is reduced while employing the metal electrode 36A.

Further, since the gate dielectric layer 32 is exposed during the etch process of the silicon-containing layer 33, the gate dielectric layer 32 is not etched during the etch process of the silicon-containing layer 33.

Moreover, the passivation layer 38 is formed on the exposed sidewall of the metal electrode 36A over the damascene pattern 34, preventing the metal electrode 36A from being oxidized during a subsequent process.

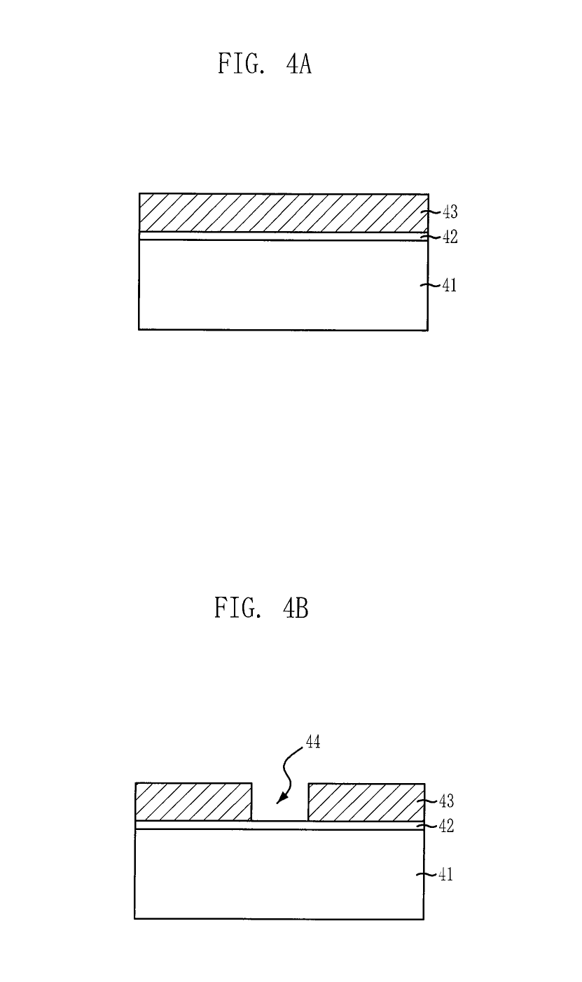

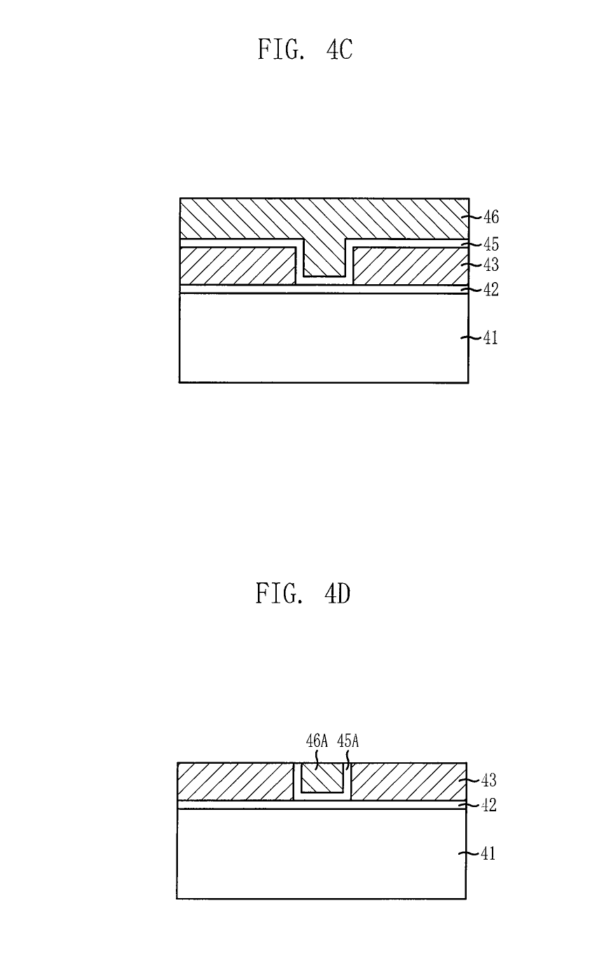

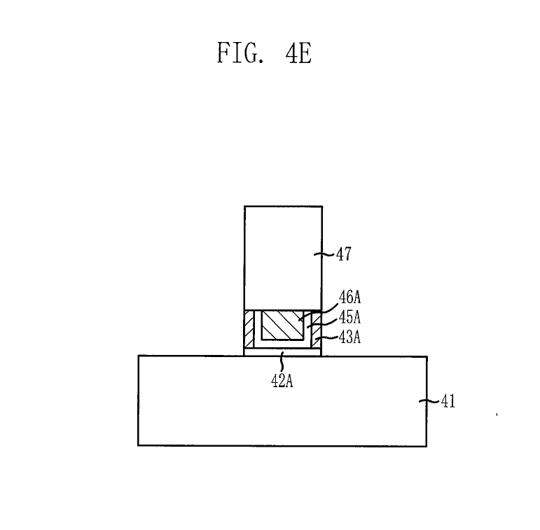

FIGS. 4A to 4E are cross-sectional views of a method for fabricating a metal gate of a semiconductor device in accordance with a third embodiment of the present invention.

Referring to FIG. 4A, a gate dielectric layer 42 is formed over a substrate 41. The substrate 41 may include a silicon substrate, in which a recess pattern or a bulb recess pattern may be formed in advance for increasing a channel length. The gate dielectric layer 42 may include a silicon oxide layer.

A silicon-containing layer 43 having a predetermined thickness is deposited over the gate dielectric layer 42. The silicon-containing layer 43 may include a polysilicon layer.

Referring to FIG. 4B, the silicon-containing layer 43 may be selectively etched to form a damascene pattern 44. The damascene pattern 44 is a line pattern formed in a region where a gate will be formed. The damascene pattern 44 is formed such that it exposes the gate dielectric layer 42. That is, the damascene pattern 44 penetrates the silicon-containing layer 43 to expose the gate dielectric layer 42.

Referring to FIG. 4C, a first metal layer 45 is deposited over the silicon-containing layer 43 with the damascene pattern 44. The first metal layer 45 may include a Ti layer. For example, the first metal layer 45 may include a bilayered structure of a Ti layer and a WN layer. Alternatively, the first metal layer 45 may include a multi-stacked structure of a Ti layer, a TiN layer and a WN layer.

Thereafter, a second metal layer 46 is deposited over the first metal layer 45 to fill the damascene pattern 44. The second metal layer 46 includes a tungsten layer, and may be deposited using a CVD process.

Referring to FIG. 4D, a polish process is performed to leave a diffusion barrier layer 45A resulting from the first metal layer 45 and a metal electrode 46A resulting from the second metal layer 46, inside the damascene pattern 44. The diffusion barrier layer 45A is formed on a bottom and a sidewall of the damascene pattern 44. The metal electrode 46A is surrounded by the diffusion barrier layer 45A and fills the damascene pattern 44.

The polish process may be performed using a chemical mechanical polishing (CMP) process. The diffusion barrier layer 45A prevents inter-diffusion between the metal electrode 46A and a silicon electrode to be formed from the silicon-containing layer 43.

Referring to FIG. 4E, a gate hard mask layer (not shown) is deposited over the silicon-containing layer 43 with the metal electrode 46A filling the damascene pattern 44. The gate hard mask layer is patterned to form a gate hard mask pattern 47. A patterning width of the gate hard mask layer is greater than a linewidth of the damascene pattern 44. The gate hard mask layer includes a nitride layer, particularly a silicon nitride layer.

The silicon-containing layer 43 is etched using the gate hard mask pattern 47 as an etch barrier to form a passivation layer 43A. As a result, the gate dielectric layer 42 is exposed. Since the silicon-containing layer 43 is a polysilicon layer, the gate dielectric layer made of oxide material has a high etch selectivity ratio to the polysilicon layer so that the gate dielectric layer 42 is not etched.

The silicon-containing layer 43 is etched using the gate hard mask pattern 47. Thus, sidewalls of the metal electrode 46A and the diffusion barrier layer 45A are surrounded by the passivation layer 43A. Because the diffusion barrier layer 45A is formed on the bottom and sidewall of the damascene pattern 44, the diffusion barrier layer 45A can sufficiently prevent the interdiffusion between the metal electrode 46A and the passivation layer 43A.

The passivation layer 43A does not serve as a gate electrode but prevents the sidewalls of the diffusion barrier layer 45A and the metal electrode 46A from being oxidized due to oxygen penetration during a subsequent process, e.g., gate re-oxidation process. That is, the passivation layer 43A of silicon material exhibits a high reactivity with oxygen and thus reacts with penetrated oxygen first, so that a portion of the passivation layer 43A is oxidized. Consequently, oxygen does not penetrate further, thus making it possible to prevent a titanium nitride layer and a tungsten layer used as the diffusion barrier layer 45A and the metal electrode 46A from being oxidized.

The gate dielectric layer 42 is etched to complete a gate patterning process such that a gate dielectric pattern 42A remains.

By the above-described processes, the gate resistance can be reduced because a silicon electrode is not disposed between the metal electrode 46A and the gate dielectric layer 42.

Further, since the gate dielectric layer 42 is exposed during the etch process of the silicon-containing layer 43, the gate dielectric layer 42 is not etched during the etch process of the silicon-containing layer 43.

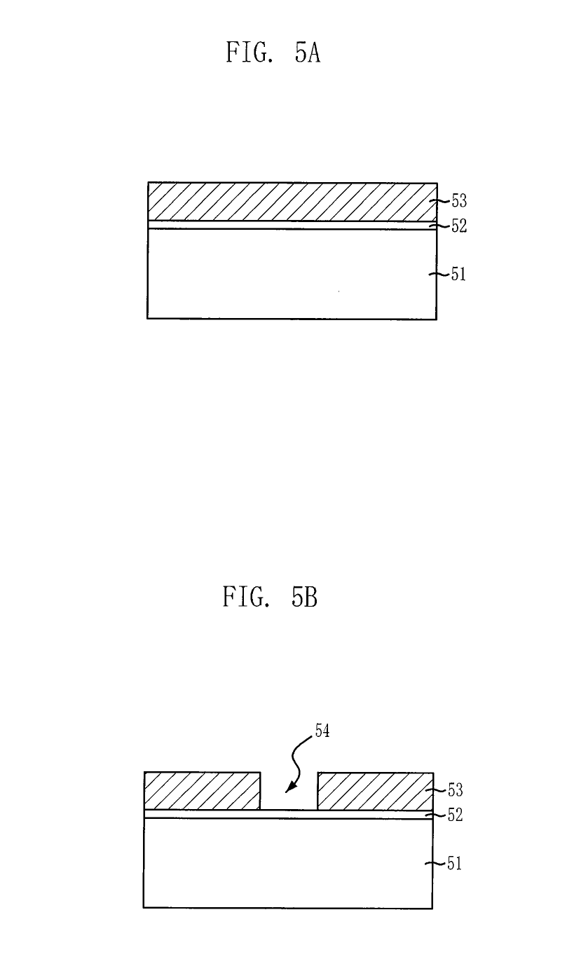

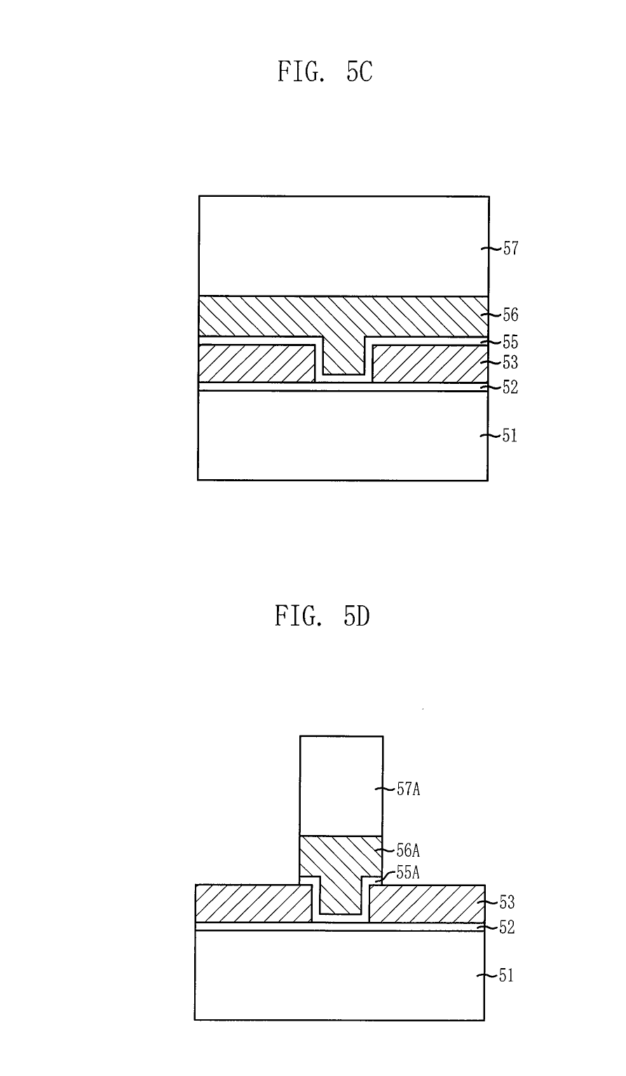

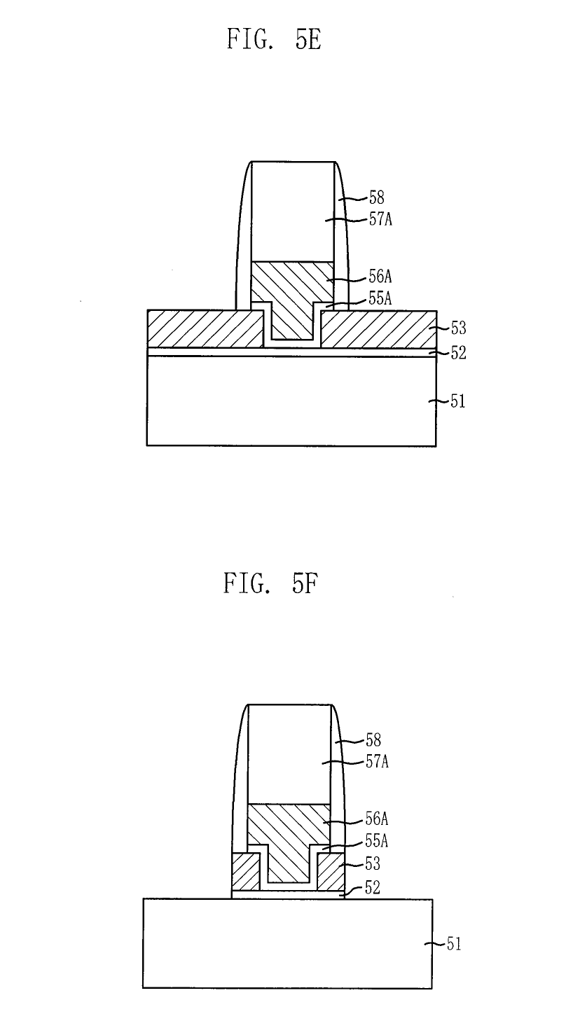

FIGS. 5A to 5F are cross-sectional views of a method for fabricating a metal gate of a semiconductor device in accordance with a fourth embodiment of the present invention.

Referring to FIG. 5A, a gate dielectric layer 52 is formed over a substrate 51. The substrate 51 may include a silicon substrate, in which a recess pattern or a bulb recess pattern may be formed in advance for increasing a channel length. The gate dielectric layer 52 may include a silicon oxide layer.

A silicon-containing layer 53 having a predetermined depth is deposited over the gate dielectric layer 52. The silicon-containing layer 53 may include a polysilicon layer.

Referring to FIG. 5B, the silicon-containing layer 53 may be selectively etched to form a damascene pattern 54. The damascene pattern 54 is a line pattern formed in a region where a gate will be formed. The damascene pattern 54 is formed such that it exposes the gate dielectric layer 52. That is, the damascene pattern 54 penetrates the silicon-containing layer 53 to expose a surface of the gate dielectric layer 52.

Referring to FIG. 5C, a first metal layer 55 is deposited over the silicon-containing layer 53 with the damascene pattern 54. The first metal layer 55 may include a Ti layer. For example, the first metal layer 55 may include a bilayered structure of a Ti layer and a WN layer. Alternatively, the first metal layer 55 may include a multi-stacked structure of a Ti layer, a TiN layer and a WN layer.

A second metal layer 56 is deposited over the first metal layer 55 to fill the damascene pattern 54. The second metal layer 56 includes a tungsten layer, and may be deposited using a CVD process. Subsequently, a gate hard mask layer 57 is formed over the second metal layer 56. The gate hard mask layer 57 includes a nitride layer, particularly a silicon nitride layer.

Referring to FIG. 5D, the gate hard mask layer 57 is patterned to form a gate hard mask pattern 57A. The pattering process of the gate hard mask layer 57 is performed using a photoresist layer (not shown) as an etch barrier. A patterning linewidth of the gate hard mask pattern 57A is greater than a linewidth of the damascene pattern 54.

The second and first metal layers 56 and 55 are etched using the gate hard mask pattern 57A as an etch barrier, thus forming a diffusion barrier layer 55A resulting from the first metal layer 55 and a metal electrode 56A resulting from the second metal layer 56.

The diffusion barrier layer 55A is formed on the bottom and the sidewall of the damascene pattern 54. Both ends of the diffusion barrier layer 55A extend to top corners of the damascene pattern 54. The metal electrode 56A is formed to a predetermined thickness over the damascene pattern 54 while filling the damascene pattern 54 over the diffusion barrier layer 55A.

The diffusion barrier layer 55A prevents inter-diffusion between the metal electrode 56A and a silicon electrode to be formed from the silicon-containing layer 53.

Referring to FIG. 5E, a first passivation layer 58 is formed over the sidewalls of the gate hard mask pattern 57A and the metal electrode 56A. The first passivation layer 58 covers the exposed sidewalls of the diffusion barrier layer 55A, thereby protecting the sidewalls of the metal electrode 56A.

The first passivation layer 58 is formed as a spacer through a blanket-etch process after depositing a nitride layer. The first passivation layer 58 prevents the metal electrode 56A from being oxidized during a subsequent thermal process, e.g., a gate re-oxidation process.

Referring to FIG. 5F, the silicon-containing layer 53 is etched using the gate hard mask pattern 57A and the first passivation layer 58 as an etch barrier to form a second passivation layer 53A. As a result, the gate dielectric layer 52 is exposed. Since the silicon-containing layer 53 is a polysilicon layer, the gate dielectric layer 52 made of oxide material has a high etch selectivity ratio to the polysilicon layer so that the gate dielectric layer 52 is not etched.

Since the second passivation layer 53A is formed using the first passivation layer 58 as an etch barrier, the sidewalls of the metal electrode 56A and the diffusion barrier layer 55A filling the damascene pattern 54 are surrounded by the second passivation layer 53A. Because the diffusion barrier layer 55A is formed on the bottom and sidewall of the damascene pattern 54, the diffusion barrier layer 55A can sufficiently prevent the inter-diffusion between the metal electrode 56A and the second passivation layer 53A.

The second passivation layer 53A does not serve as a gate electrode but prevents the sidewalls of the diffusion barrier layer 55A and the metal electrode 56A from being oxidized due to oxygen penetration during a subsequent process, e.g., gate re-oxidation process. That is, the second passivation layer 53A of silicon material exhibits a high reactivity with oxygen and thus reacts with penetrated oxygen first, so that a portion of the second passivation layer 53A is oxidized. Consequently, oxygen does not penetrate further, thus preventing oxidation of a titanium nitride layer and a tungsten layer used as the diffusion barrier layer 55A and the metal electrode 56A.

The gate dielectric layer 52 is etched to complete a gate patterning process, resulting in a gate dielectric pattern 52A under the second passivation layer 53A.

By the above-described processes, the gate resistance can be reduced because a silicon electrode is not disposed on the gate dielectric layer 52 but is directly disposed on the metal electrode 56A.

Further, since the gate dielectric layer 52 is exposed during the etch process of the silicon-containing layer 53, the gate dielectric layer 52 is not etched during the etch process of the silicon-containing layer 53.

The first passivation layer 58 is formed on the exposed sidewall of the metal electrode 56A over the damascene pattern, and the second passivation layer 53A is formed on the sidewall of the diffusion barrier layer 55A inside the damascene pattern 54. Accordingly, oxidation of the metal electrode 56A and the diffusion barrier layer 55A is prevented during a subsequent process.

In accordance with the embodiments, the silicon-containing layer is partially etched and the metal electrode is then etched, so that a space between the metal electrode and the gate dielectric layer decreases, thereby reducing resistance.

Furthermore, the silicon-containing layer on the sidewall of the metal electrode is etched to increase an etch selectivity ratio of the gate dielectric layer, preventing the gate dielectric layer from being etched.

In addition, since the metal electrode is disposed in the passivation layer resulting from the silicon-containing layer, the metal electrode is not externally exposed, thus preventing oxidization of the metal electrode.

Moreover, it is possible to achieve an oxidation effect of the sidewall of the silicon electrode during a subsequent process of forming an insulation layer through sidewall oxidation, which is referred to as a gate re-oxidation process.

While the present invention has been described with respect to the specific embodiments, it will be apparent to those skilled in the art that various changes and modifications may be made without departing from the spirit and scope of the invention as defined in the following claims.

What is claimed is:

1. A semiconductor device, comprising:
a substrate;
a gate dielectric layer over the substrate;
a silicon electrode over the gate dielectric layer, wherein the silicon electrode comprises a damascene pattern;
a diffusion barrier layer on a bottom and a sidewall of the damascene pattern; and
a metal electrode over the diffusion barrier layer, wherein the metal electrode fills the damascene pattern.

2. The semiconductor device of claim 1, wherein the metal electrode includes a first region filling the damascene pattern and a second region, wherein the metal electrode has a predetermined thickness over the first region.

3. The semiconductor device of claim 2, further comprising a passivation layer over sidewalls of the second region.

4. The semiconductor device of claim 3, wherein the passivation layer includes a nitride layer.

5. The semiconductor device of claim 1, wherein the silicon electrode includes a polysilicon layer, and the metal electrode includes a tungsten (W) layer.

6. The semiconductor device of claim 1, wherein the diffusion barrier layer includes a bilayered structure of a titanium (Ti) layer and a tungsten nitride (WN) layer or a multi-stacked structure of a titanium layer, a titanium nitride (TiN) layer and a tungsten nitride layer.

7. A semiconductor device, comprising:
a substrate;
a gate dielectric layer over the substrate;
a metal electrode over the gate dielectric layer; and
a diffusion barrier layer between the metal electrode and the gate dielectric layer, wherein the diffusion barrier layer covers a sidewall of the metal electrode.

8. The semiconductor device of claim 7, further comprising:
a gate hard mask layer over a top of the metal electrode; and
a passivation layer over a sidewall of the diffusion barrier layer.

9. The semiconductor device of claim 8, wherein the gate hard mask layer includes a nitride layer, and the passivation layer includes a polysilicon layer.

10. The semiconductor device of claim 7, wherein the metal electrode includes a first region of which a sidewall is covered by the diffusion barrier layer, and a second region of which a sidewall is externally exposed, the second region being disposed over the first region.

11. The semiconductor device of claim 10, further comprising:
a gate hard mask layer over a top of the second region;
a first passivation layer over the sidewall of the second region; and
a second passivation layer over a sidewall of the diffusion barrier layer.

12. The semiconductor device of claim 11, wherein the gate hard mask layer and the first passivation layer include a nitride layer, and the second passivation layer includes a polysilicon layer.

13. The semiconductor device of claim 7, wherein the substrate includes a recess pattern or a bulb recess pattern.

14. A method for fabricating a semiconductor device, the method comprising:
providing a substrate;
forming a gate dielectric layer over the substrate;
forming a silicon-containing layer over the gate dielectric layer;
forming a damascene pattern in the silicon-containing layer;
forming a diffusion barrier layer on a bottom and a sidewall of the damascene pattern;
forming a metal electrode over the diffusion barrier layer, wherein the metal electrode fills the damascene pattern;
forming a gate hard mask layer over the metal electrode, wherein the gate hard mask layer has a greater linewidth than the damascene pattern; and
sequentially etching the silicon-containing layer and the gate dielectric layer using the gate hard mask layer as an etch barrier.

15. The method of claim 14, wherein the damascene pattern has a depth such that the silicon-containing layer is formed to have a predetermined thickness over the gate dielectric layer.

16. The method of claim 14, wherein the damascene pattern has a depth such that the gate dielectric layer is exposed.

17. The method of claim 14, wherein the silicon-containing layer includes a polysilicon layer.

18. The method of claim 14, wherein the metal electrode includes a tungsten layer.

19. The method of claim 14, wherein the diffusion barrier layer includes a bilayered structure of a Ti layer and a WN layer or a multi-stacked structure of a Ti layer, a TiN layer and a WN layer.

20. A method for fabricating a semiconductor device, the method comprising:
providing a substrate;
forming a gate dielectric layer over the substrate;
forming a silicon-containing layer over the gate dielectric layer, wherein the silicon-containing layer includes a damascene pattern;
forming a diffusion barrier layer over the silicon-containing layer;
forming a metal electrode over the diffusion barrier layer, wherein a portion of the metal electrode fills the damascene pattern;
forming a gate hard mask layer over the metal electrode, wherein the gate hard mask layer has a greater linewidth than the damascene pattern;
etching the metal electrode and the diffusion barrier layer using the gate hard mask layer as an etch barrier;
forming a passivation layer on an exposed sidewall of the metal electrode; and
sequentially etching the silicon-containing layer and the gate dielectric layer using the gate hard mask layer and the passivation layer as an etch barrier.

21. The method of claim 20, wherein the damascene pattern has a depth such that the silicon-containing layer is formed to have a predetermined thickness over the gate dielectric layer.

22. The method of claim 20, wherein the damascene pattern has a depth such that the gate dielectric layer is exposed.

23. The method of claim 20, wherein the passivation layer is formed by a blanket-etch process after depositing a nitride layer.

24. The method of claim 20, wherein the diffusion barrier layer includes a bilayered structure of a Ti layer and a TN layer or a multi-stacked structure of a Ti layer, a TN layer and a TN layer.

25. The method of claim 20, wherein the substrate includes a recess pattern or a bulb recess pattern.
